(19) United States
(12) Patent Application Publication
(10) Pub. No.: US 2014/0202514 A1
(43) Pub. Date: Jul. 24, 2014

(54) PHOTOVOLTAIC ASSEMBLY WITH PROTECTIVE COVER

(71) Applicant: HON HAI PRECISION INDUSTRY CO., LTD., New Taipei (TW)

(72) Inventors: YU-CHEN TING, New Taipei (TW); CHIH-HANG CHAO, New Taipei (TW)

(73) Assignee: HON HAI PRECISION INDUSTRY CO., LTD., New Taipei (TW)

(21) Appl. No.: 14/037,419

(22) Filed: Sep. 26, 2013

(30) Foreign Application Priority Data
Jan. 18, 2013 (TW) 102101983

(51) Int. Cl. H01L 31/048

(52) U.S. Cl. CPC H01L 31/048
USPC 136/244

(57) ABSTRACT

A photovoltaic assembly includes a solar plate and a protective cover. The protective cover covers one side of the solar plate and includes a cover body. The protective cover is rotatable relative to the solar plate between a closed position and an open position. When the protective cover is in the closed position, the cover body covers the solar plate and is substantially parallel to the solar plate to prevent foreign matter from adhering to the solar plate. When the protective cover is in the open position, an angle is defined between the cover body and the solar plate so that the foreign matter slides off the cover body.

### BACKGROUND

1. Technical Field

The present disclosure relates to photovoltaic assemblies, and more particularly to a photovoltaic assembly having a protective cover.

2. Description of Related Art

A photovoltaic device is used to change solar energy into electric energy. The photovoltaic device includes a solar plate for absorbing sunlight. However, foreign matter, such as snow or dust, may pile on the solar plate outdoors and reduce the solar plate's ability to receive sunlight. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like-reference numerals designate corresponding parts throughout the several views.

FIG. 1 is an isometric view of a photovoltaic assembly having a cover body in an open position, in accordance with one embodiment.

FIG. 2 is similar to FIG. 1, but the cover body is in a closed position.

FIG. 3 is an isometric view of a photovoltaic assembly having a cover body in an open position, in accordance with another embodiment.

FIG. 4 is an enlarged view of a circled portion IV of FIG. 3.

FIG. 5 is similar to FIG. 3, but the cover body is in a closed position.

FIG. 6 is a block view of the photovoltaic assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

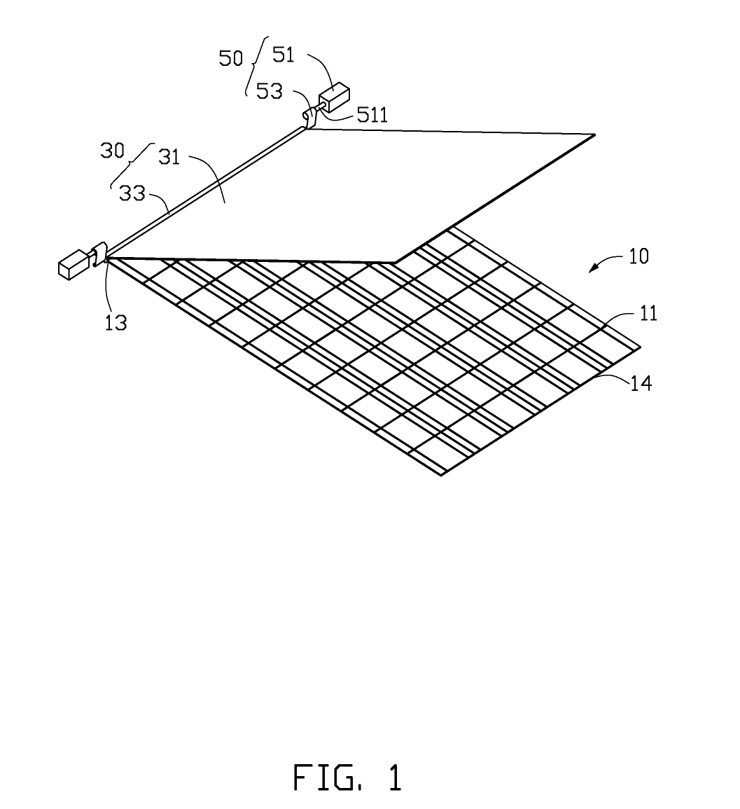

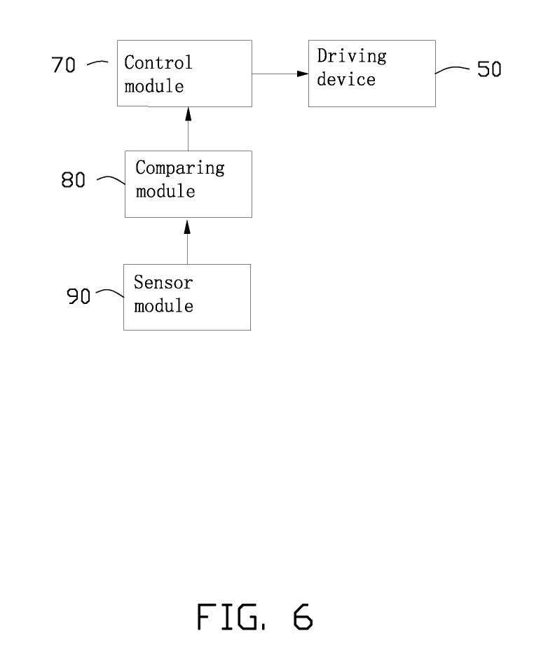

FIGS. 1 and 6 illustrate a photovoltaic assembly in accordance with a first embodiment. The photovoltaic assembly includes a solar plate 10, a protective cover 30, two driving devices 50, a control module 70, a comparing module 80, and a sensor module 90.

The solar plate 10 includes a front surface 11, a rear surface (not shown) opposite to the front surface 11, a first side edge 13, and a second side edge 14. In one embodiment, the first side edge 13 is substantially parallel to the second side edge 14, and the solar plate 10 is substantially rectangular. The front surface 11 absorbs sunlight.

The protective cover 30 is located on one side of the solar plate 10 and includes a cover body 31 and a pivot shaft 33. The cover body 31 is substantially rectangular and is transparent so that sunlight passes through the cover body to the solar plate 10. In this embodiment, a width of the protective cover 30 is equal to a width of the solar plate 10, and a length of the protective cover 30 is equal to a length of the solar plate 10. The cover body 31 is a high-borosilicate glass, so it is not easily broken. The pivot shaft 33 is adjacent to the first side edge 13 of the solar plate 10 and is rotatably secured to a supporting mechanism (not shown). A length of the pivot shaft 33 is greater than the width of the protective cover 30. Thus, two opposite ends of the pivot shaft 33 are exposed out of the protective cover 30.

FIGS. 1-6 show that in one embodiment, each of the two driving devices 50 includes a motor 51 and a belt 53. The motor 51 has a driving shaft 511. One end of the belt 53 is wrapped around the driving shaft 511, and another end of the belt 53 is wrapped around the pivot shaft 33.

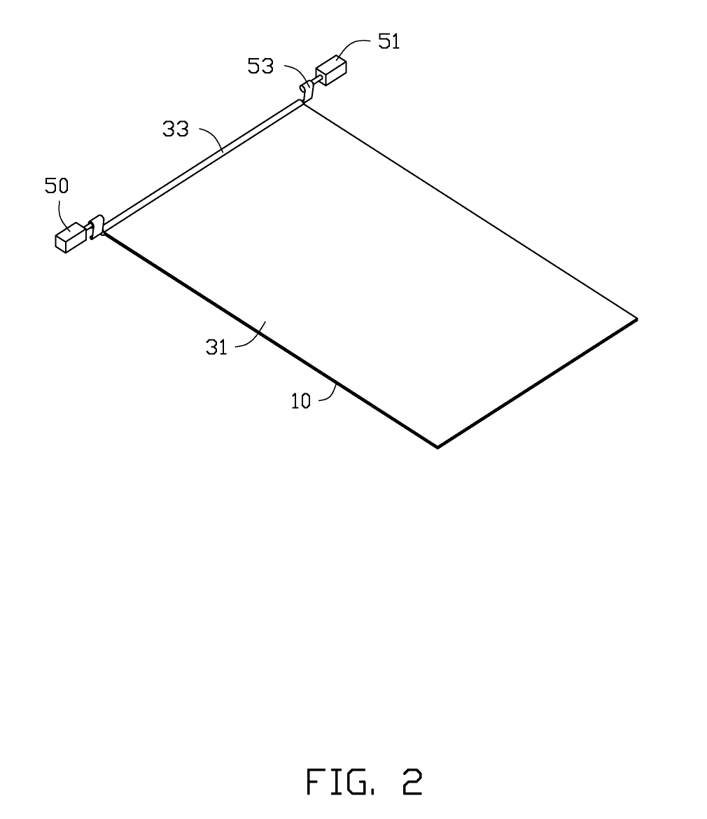

FIG. 2 shows the protective cover 30 in a closed position, where the cover body 31 is substantially parallel to and covers the solar plate 10 to prevent foreign matter, such as snow, dust, and so on, from adhering to the solar plate 10. The sensor module 90 senses a weight value of the protective cover 30 and sends the weight value to the comparing module 80. The comparing module 80 judges whether or not the weight value is greater than a predetermined minimum value. When the weight value is greater than the predetermined minimum value, the comparing module 80 sends an open signal to the control module 70, and the control module 70 starts the motors 51. The motors 51 drive the corresponding driving shafts 511 to rotate along a first direction so that the driving shafts 511 pull the corresponding belts 53. The belts 53 rotate the pivot shaft 33 along a second direction opposite to the first direction to open the cover body 31. Thus, the protective cover 30 is in an open position and is angled relative to the solar plate 10, so that the foreign matter slides off the cover body 31. In this embodiment, the angle is greater than 60 degrees and smaller than 90 degrees. In other embodiments, the angle is 90 degrees.

When the weight value is smaller than the predetermined minimum value, the comparing module 80 sends a close signal to the control module 70. The control module 70 starts the motors 51, the motors 51 drive corresponding driving shafts 511 to rotate along the second direction, the belts 53 resiliently rebound, and the pivot shaft 33 rotates along the first direction, until the cover body 31 returns to the closed position.

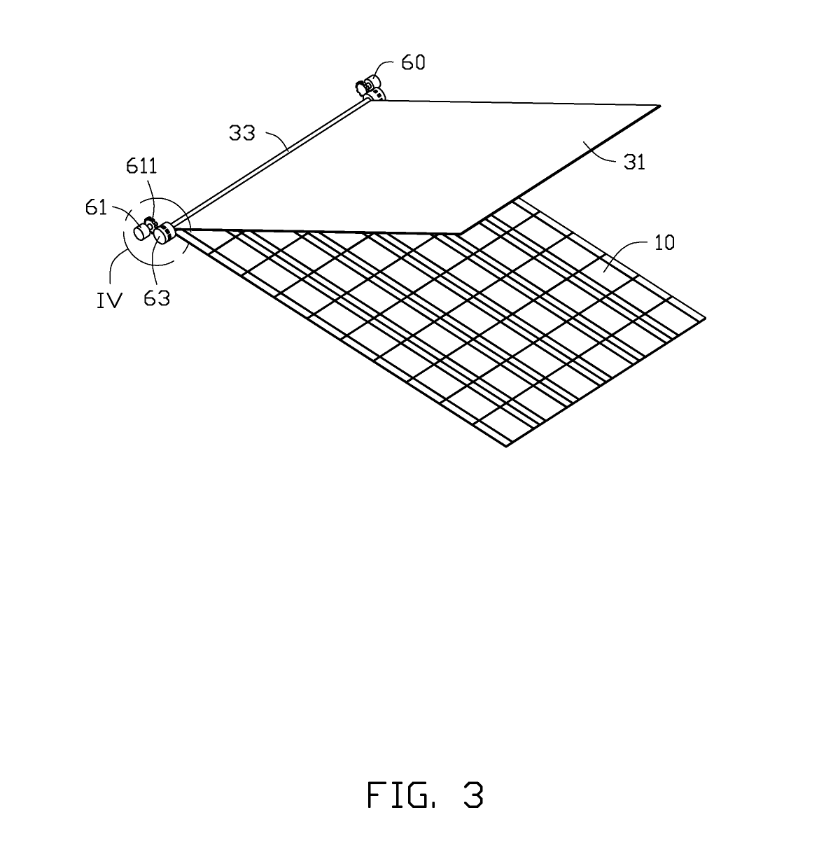

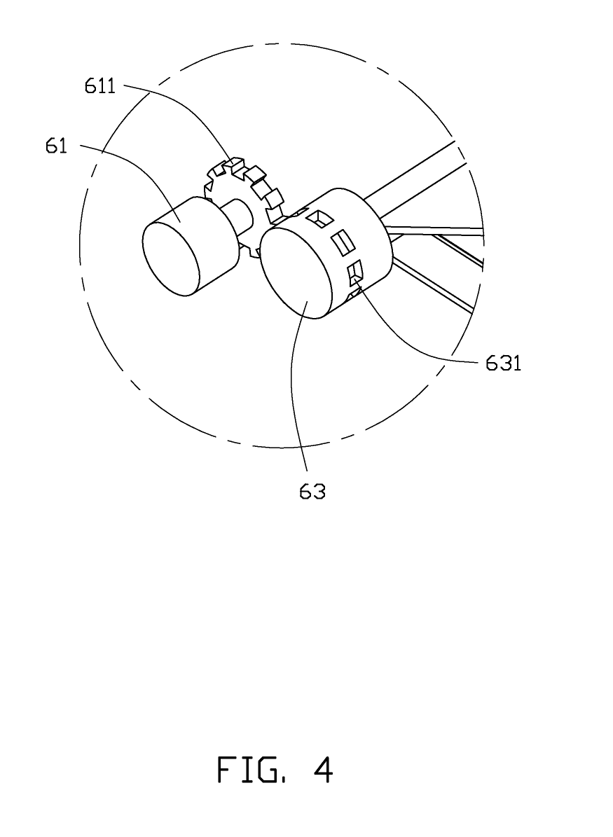

FIGS. 3-4 illustrate that in another embodiment, the photovoltaic assembly has two driving devices 60. Each driving device 60 includes a motor 61 and a rotating post 63. The motor 61 is connected to a driving gear 611. The rotating post 63 is substantially columnar and defines a plurality of pressed slots 631 so that the driving gear 611 meshes with the rotating post 63. The rotating posts 63 of the two driving devices 60 are installed on two opposite ends of the pivot shaft 33, respectively.

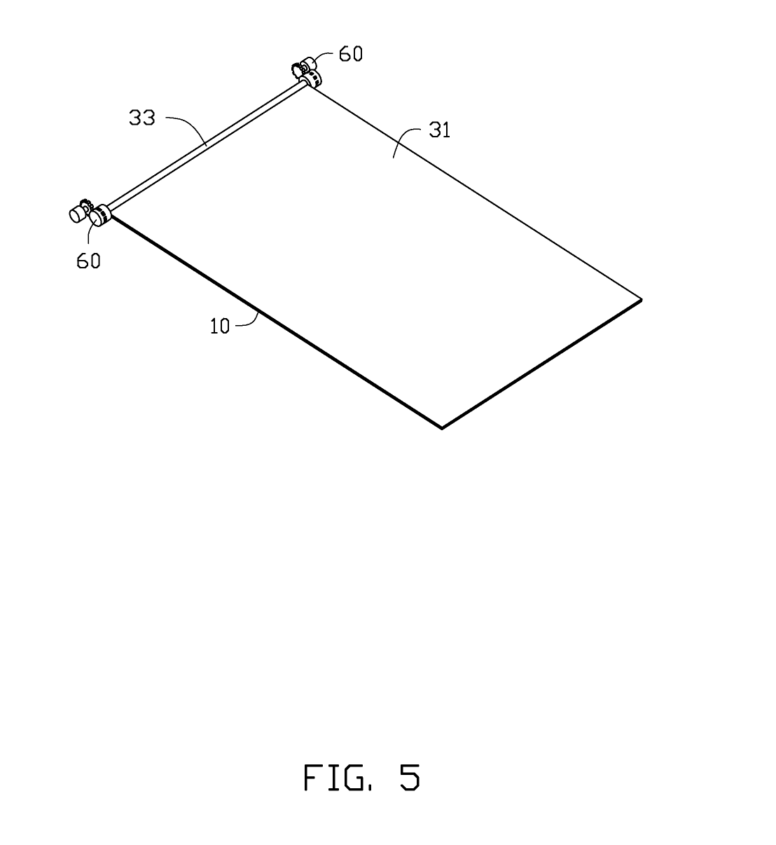

FIG. 5 shows the protective cover 30 in a closed position, where the cover body 31 covers the solar plate 10 and is substantially parallel to the solar plate 10. The sensor module 90 senses a weight value of the protective cover 30 and sends the weight value to the comparing module 80. The comparing module 80 judges whether or not the weight value is greater than a predetermined minimum value. When the weight value is greater than the predetermined minimum value, the comparing module 80 sends an open signal to the control module 70, and the control module 70 starts the motors 61. The motors 61 rotate the corresponding driving gears 611 along a first direction, and the driving gears 611 rotate the corresponding rotating post 63 along a second direction opposite to the first direction. The pivot shaft 33 rotates with the rotating posts 63 along the second direction until an angle is defined between the cover body 31 and the solar plate 10. Thus, the protective cover 30 is in an open position, and the foreign matter slides off the cover body 31. In this embodiment, the angle is greater than 60 degrees and smaller than 90 degrees. In other embodiments, the angle is 90 degrees.

When the weight value is smaller than the predetermined minimum value, the comparing module 80 sends a close signal to the control module 70. The control module 70 starts the motors 51, the motors 51 rotate the corresponding driving gears 611 along the second direction, and the driving gears 611 rotate the corresponding rotating posts 63 along the first direction. The pivot shaft 33 rotates with the rotating posts 63 along the first direction until the cover body 31 returns to the closed position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A photovoltaic assembly comprising:
a solar plate; and
a protective cover located on one side of the solar plate and comprising a cover body;
wherein the protective cover is rotatable relative to the solar plate between a closed position and an open position; when the protective cover is located on the closed position, the cover body covers the solar plate and is substantially parallel to the solar plate; and when the protective cover is located on the open position, an angled is defined between the cover body and the solar plate.

2. The photovoltaic assembly of claim 1, wherein a width of the cover body is greater than a width of the solar plate, and a length of the cover body is greater than a length of the solar plate.

3. The photovoltaic assembly of claim 1, further comprising two driving devices, wherein the protective cover further comprises a pivot shaft located on one side of the cover body, and the two driving devices drive the protective cover to rotate from the closed position to the open position.

4. The photovoltaic assembly of claim 3, wherein each of the two driving devices comprises a motor and a belt, the motor has a driving shaft; the belt is resiliently deformable to connect the driving shaft to the pivot shaft; and the motor rotates the driving shaft to rotate the protective cover.

5. The photovoltaic assembly of claim 4, wherein the belt resiliently rebounds to rotate the protective cover from the open position to the closed position.

6. The photovoltaic assembly of claim 3, wherein each of the two driving devices comprises a driving gear and a rotating post; the rotating post of each of the two driving devices is installed on the pivot shaft; and the driving gear is meshed with the rotating post.

7. The photovoltaic assembly of claim 6, wherein each of the two driving devices further comprises a motor; and the motor is connected to the driving gear.

8. The photovoltaic assembly of claim 1, wherein the cover body is transparent.

9. The photovoltaic assembly of claim 1, wherein the cover body is made by high-borosilicate glass.

10. A photovoltaic assembly comprising:
a solar plate comprising a first side edge and a second edge parallel to the first side edge; and
a protective cover comprising a cover body and a pivot shaft located on one side of the cover body, and the pivot shaft adjacent to the first side edge;
wherein the protective cover is rotatable relative to the solar plate between a closed position and an open position; when the protective cover is located on the closed position, the cover body covers the solar plate and is substantially parallel to the solar plate; and when the protective cover is located on the open position, an angled is defined between the cover body and the solar plate.

11. The photovoltaic assembly of claim 10, wherein a width of the cover body is greater than a width of the solar plate; and a length of the cover body is greater than a length of the solar plate.

12. The photovoltaic assembly of claim 10, further comprising two driving devices, wherein the two driving devices drive the pivot shaft to rotate the protective cover from the closed position to the open position.

13. The photovoltaic assembly of claim 12, wherein each of the two driving devices comprises a motor and an belt, the motor has a driving shaft; the belt is resiliently deformable to connect the driving shaft to the pivot shaft, and the motor rotates the driving shaft to rotate the protective cover.

14. The photovoltaic assembly of claim 13, wherein the belt resiliently rebounds to rotate the protective cover from the open position to the closed position.

15. The photovoltaic assembly of claim 12, wherein each of the two driving devices comprises a driving gear and a rotating post; the rotating post of each of the two driving devices is installed on the pivot shaft, and the driving gear is meshed with the rotating shaft.

16. The photovoltaic assembly of claim 15, wherein each of the two driving devices further comprises a motor, and the motor is connected to the driving gear.

17. The photovoltaic assembly of claim 10, wherein the cover body is transparent.

18. The photovoltaic assembly of claim 10, wherein the cover body is made by high-borosilicate glass.
